(19) United States
(12) Patent Application Publication
(10) Pub. No.: US 2024/0288503 A1
(43) Pub. Date: Aug. 29, 2024

(54) CORRECTION DEVICE, ENERGY STORAGE APPARATUS, AND CORRECTION METHOD

(71) Applicant: GS Yuasa International Ltd., Kyoto-shi, Kyoto (JP)

(72) Inventors: Yuki IMANAKA, Kyoto (JP); Seiji TAKAI, Kyoto (JP)

(21) Appl. No.: 18/563,639

(22) PCT Filed: Apr. 13, 2022
(86) PCT No.: PCT/JP2022/017697

§ 371 Date: Nov. 22, 2023

(30) Foreign Application Priority Data
May 28, 2021 (JP) 2021-090028

(51) Int. Cl. G01R 31/387; G01R 31/36

(52) U.S. Cl. CPC G01R 31/387; G01R 31/3648

(57) ABSTRACT

A correction device that corrects a measured value of a current of an energy storage cell or an assembled battery is configured to calculate a correction value of the measured value of the current based on an SOC difference between a first SOC of the energy storage cell or the assembled battery estimated based on an integrated value of the measured values of the current and a second SOC of the energy storage cell or the assembled battery estimated based on a voltage of the energy storage cell or the assembled battery and is configured to correct the measured value of the current based on the calculated correction value.

### CROSS REFERENCE TO RELATED APPLICATIONS

This application is a National Stage Application, filed under 35 U.S.C. § 371, of International Application No. PCT/JP2022/017697, filed Apr. 13, 2022, which international application claims priority to and the benefit of Japanese Application No. 2021-090028, filed May 28, 2021; the contents of both of which as are hereby incorporated by reference in their entireties.

### BACKGROUND

### Technical Field

The present invention relates to a technique for correcting a measured value of a current.

### Description of Related Art

There has been known a technique where a current or a voltage of an energy storage cell or an assembled battery is measured, and a state of charge (SOC) of the energy storage cell or the assembled battery is estimated from these measurement results. Patent Literature JP-A-2010-283922 discloses a technique where, in order to enhance the estimation accuracy of an SOC, two or more different estimation means are combined with each other so as to enhance the estimation accuracy of the SOC.

### BRIEF SUMMARY

The measured value of a current of the energy storage cell or the assembled battery includes a measurement error caused by a current sensor. In an SOC estimation value of an energy storage cell or an assembled battery estimated based on an integrated value of measured values of a current, measurement errors of the current are accumulated along with the supply of the current to the energy storage cell or the assembled battery.

The present invention discloses a technique where a correction value is calculated, and a measured value of a current is corrected based on the correction value.

A correction device that corrects a measured value of a current of an energy storage cell or an assembled battery is configured to calculate a correction value of the measured value of the current based on an SOC difference between a first SOC of the energy storage cell or the assembled battery estimated based on an integrated value of the measured values of the current and a second SOC of the energy storage cell or the assembled battery estimated based on a voltage of the energy storage cell or the assembled battery, and is configured to correct the measured value of the current based on the calculated correction value.

The present invention is applicable to an energy storage apparatus, and an energy storage apparatus for a vehicle. The present invention is also applicable to a correction method of correcting a measured value of a current, and a program for correcting a measured value of a current.

According to the above configuration, the correction value is obtained by focusing on the relationship between the measurement error of the current and the SOC estimation value, and the measured value of the current is corrected based on the correction value. As a result, the measurement accuracy of the current of the energy storage cell or the assembled battery can be enhanced. By improving the current measurement accuracy, the accuracy of the SOC estimation based on the current integration can be enhanced.

### BRIEF DESCRIPTION OF THE FIGURES

FIG. 1 is a side view of an automobile according to an embodiment 1.

FIG. 2 is an exploded perspective view of a battery.

FIG. 3 is a plan view of a secondary battery cell.

FIG. 4 is a cross-sectional view taken along a line A-A in FIG. 3.

FIG. 5 is a block diagram illustrating an electrical configuration of an automobile.

FIG. 6 is a block diagram showing an electrical configuration of the battery.

FIG. 7 is a graph illustrating an SOC-OCV correlation characteristic of an LFP/Gr-based battery.

FIG. 8 is a diagram illustrating a flowchart of SOC estimation (embodiment 1).

FIG. 9 is a diagram illustrating a flowchart of SOC estimation (embodiment 2).

### DETAILED DESCRIPTION OF VARIOUS EMBODIMENTS

### <Overall Configuration of Correction Device and Energy Storage Apparatus>

A correction device that corrects a measured value of a current of an energy storage cell or an assembled battery is configured to calculate a correction value of the measured value of the current based on an SOC difference between a first SOC of the energy storage cell or the assembled battery estimated based on an integrated value of the measured values of the current and a second SOC of the energy storage cell or the assembled battery estimated based on a voltage of the energy storage cell or the assembled battery, and is configured to correct the measured value of the current based on the calculated correction value.

The second SOC is estimated based on the voltage of the energy storage cell or the assembled battery and hence, a measurement error included in the measured value of the current is not accumulated. Accordingly, the SOC difference that is the difference between the first SOC and the second SOC is considered as an accumulated amount of measurement errors included in the first SOC. Accordingly, the measurement error included in the measured value of the current can be calculated based on this SOC difference. By correcting the measured value of the current using the calculated measurement error as the correction value, the measured value of the current can be made to approach the true value and take a value close to the true value. Accordingly, the current measurement accuracy can be enhanced.

The current measurement error includes a gain error and an offset error. An error of an SOC estimation value attributed to a gain error is canceled by charging and discharging of electricity. Accordingly, to improve the SOC estimation accuracy, it is required to reduce an influence of an offset error. It is generally considered that the detection of the offset error is difficult unless an energy storage cell or an assembled battery is brought into a no current state. In the above configuration, it is possible to calculate a measurement error (an offset error) using the SOC difference, and to correct the measured value of the current using the measurement error as the correction value without bringing the energy storage cell or the assembled battery into a no current state.

The processing of estimating the second SOC may be a processing of charging electricity to the energy storage cell or the assembled battery to a fully charged state and estimating the SOC to 100% or a value close to 100% (a full charging detection method). The full charging detection method is processing of setting the SOC of the energy storage cell or the assembled battery to a predetermined value when the energy storage cell or the assembled battery reaches a predetermined voltage value. By using the second SOC obtained by the full charging detection method where the measurement errors are not accumulated as a target to be compared with the first SOC, it is possible to obtain an accumulated amount of measurement errors with high accuracy and hence, the measured value of the current can be appropriately corrected.

An energy storage apparatus includes: the correction device; the energy storage cell or the assembled battery; a current measurement unit that measures a current of the energy storage cell or the assembled battery; and an SOC estimation unit that estimates a first SOC of the energy storage cell or the assembled battery based on an integrated value of measured values of the current of the energy storage cell or the assembled battery after the correction.

With this configuration, the SOC is estimated by integrating the measured values of the current after correction and hence, the accumulation of the measurement errors is small whereby the estimation accuracy of the first SOC can be enhanced. The estimation accuracy of the first SOC can be enhanced and hence, a usable range (an SOC range between a lower limit and an upper limit) of the energy storage cell or the assembled battery can be broadly set. When the estimation accuracy of the first SOC is low, the usable range is narrowed because the estimation error needs to be considered, but when the estimation accuracy is high, the performance of the energy storage cell or the assembled battery can be utilized to the maximum.

In a case where the SOC difference exceeds a threshold, the correction device may correct the measured value of the current. In this configuration, the correction is performed when the SOC difference is increased and hence, the expansion of the SOC difference can be suppressed whereby the lowering of the estimation accuracy of the first SOC can be suppressed. By suppressing the SOC difference to the threshold or less, it is possible to suppress the use of the energy storage cell or the assembled battery beyond the usable range. For example, in a case where the energy storage cell or the assembled battery is provided for a moving body, the energy storage cell or the assembled battery can ensure the acceptability of regenerative charging.

In a case where the SOC difference per a unit time exceeds a threshold, the correction device may correct the measured value of the current.

In a case where the change amount of the SOC difference per unit time is large, the estimation accuracy of the first SOC is lowered in a short time and hence, the difference between the first SOC and the second SOC is increased. The correction of the measured value of the current is performed when a change in the SOC difference per unit time exceeds the threshold before the SOC difference exceeds the threshold and hence, the measured value of a current can be corrected at an early stage. Accordingly, the lowering of the estimation accuracy of the first SOC can be suppressed.

The correction device may correct the measured value of the current using the correction value calculated based on a change amount of the SOC difference per unit time. For example, the correction value is calculated so as to cancel a change amount of the SOC difference per unit time, and the measured value of the current is corrected based on the correction value and hence, the lowering in the estimation accuracy of the first SOC can be suppressed.

### Embodiment 1

### 1. Description of Battery

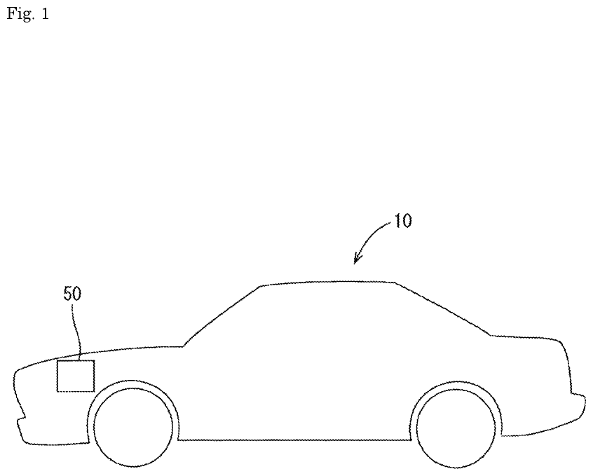

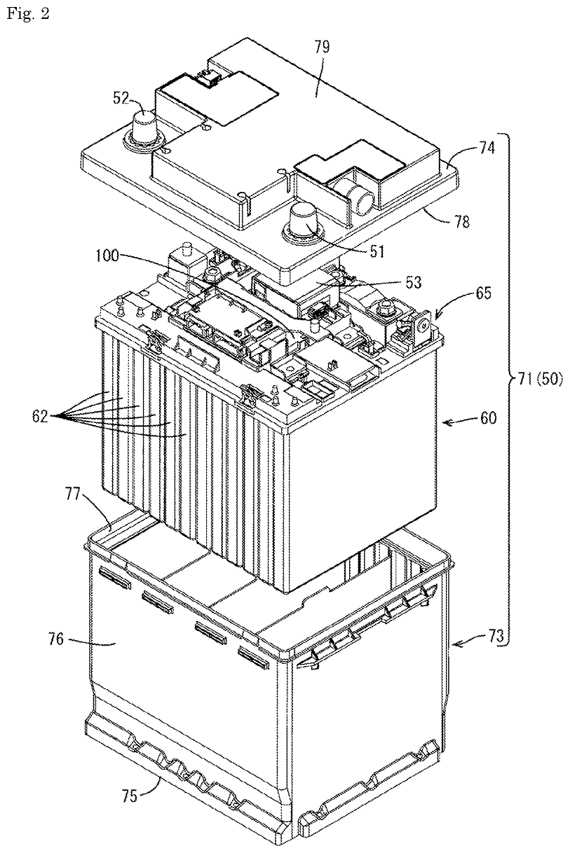

FIG. 1 is a side view of an automobile 10, and FIG. 2 is an exploded perspective view of a battery 50. The automobile 10 is an engine driven vehicle, and includes the battery 50. On the automobile 10, in place of the engine (an internal combustion engine), an energy storage apparatus or a fuel battery for driving the vehicle may be mounted. In FIG. 1, only an automobile 10 and a battery 50 are illustrated, and other components constituting the automobile 10 are not illustrated. The automobile 10 is an example of a “vehicle”, and the battery 50 is an example of an “energy storage apparatus”.

As illustrated in FIG. 2, the battery 50 includes an assembled battery 60, a circuit board unit 65, and a container 71.

The container 71 includes a body 73 made of a synthetic resin material, and a lid body 74. The body 73 has a bottomed cylindrical shape. The body 73 includes a bottom surface portion 75 and four side surface portions 76. An upper opening portion 77 is formed at an upper end portion of the body 73 by four side surface portions 76.

The container 71 contains the assembled battery 60 and the circuit board unit 65. In the configuration illustrated in FIG. 2, the assembled battery 60 has twelve secondary battery cells 62. The secondary battery cell 62 is an example of “an energy storage cell”.

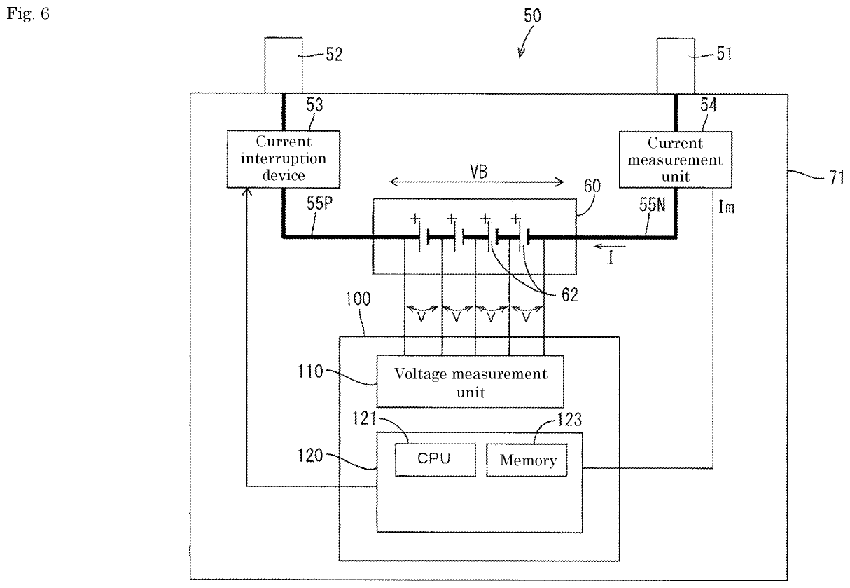

Twelve secondary battery cells 62 are connected with each other in three parallels and four series. The circuit board unit 65 is disposed above the assembled battery 60. In the block diagram in FIG. 6, three secondary battery cells 62 that are connected in parallel are indicated by one battery signal.

The lid body 74 illustrated in FIG. 2 closes the upper opening portion 77 of the body 73. An outer peripheral wall 78 is formed on a periphery of the lid body 74. The lid body 74 has a protruding portion 79 having an approximately T shape as viewed in a plan view. On a front portion (on a left front side in FIG. 2) of the lid body 74, a positive external terminal 52 is fixed to one corner portion, and a negative external terminal 51 is fixed to the other corner portion.

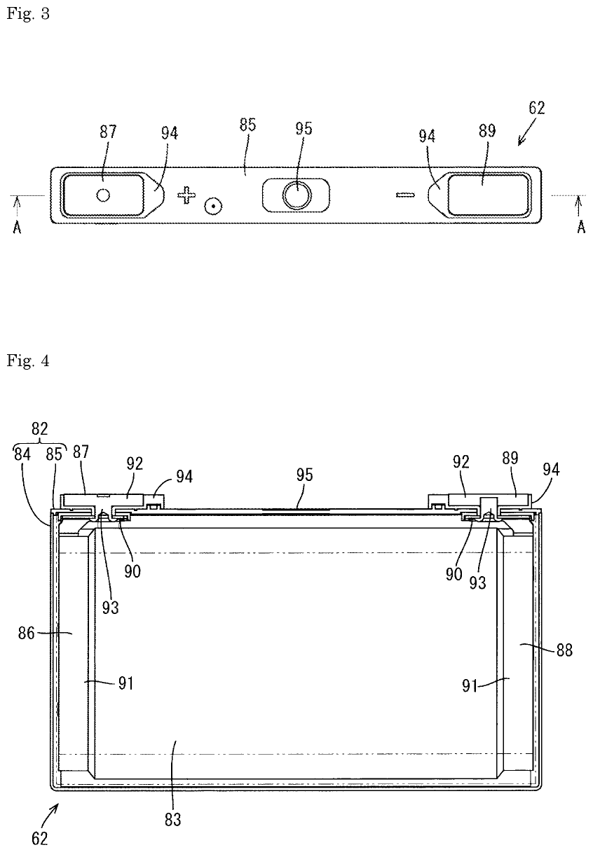

As illustrated in FIG. 3 and FIG. 4, the secondary battery cell 62 is configured such that an electrode assembly 83 is accommodated in a case 82 having a rectangular parallelepiped shape together with a nonaqueous electrolyte. In the embodiment, the secondary battery cell 62 is formed of a lithium ion secondary battery. The case 82 includes a case body 84 and a lid 85 that closes an opening portion formed at an upper portion of the case body 84.

The secondary battery cell 62 is not limited to a prismatic cell illustrated in FIG. 3 and FIG. 4, and may be a cylindrical cell or a pouch cell having a laminate film case.

The electrode assembly 83 is formed such that a separator formed of a porous resin film is disposed between a negative electrode element that is formed by applying an active material to a substrate formed of a copper foil, and a positive electrode element that is formed by applying an active material to a substrate formed of an aluminum foil. These elements all have a strip shape, and are wound in a flat shape so as to be accommodated in the case body 84 in a state where the position of the negative electrode element and the position of the positive electrode element are displaced toward opposite sides in the width direction with respect to the separator.

The electrode assembly 83 may be of a stacked type instead of a wound type.

A positive terminal 87 is connected to the positive electrode element via a positive electrode current collector 86, and a negative terminal 89 is connected to the negative electrode element via a negative electrode current collector 88 (see FIG. 4). The positive electrode current collector 86 and the negative electrode current collector 88 are each formed of a flat plate-like pedestal portion 90 and a leg portion 91 extending from the pedestal portion 90. A through hole is formed in the pedestal portion 90. The leg portion 91 is connected to the positive electrode element or the negative electrode element.

The positive terminal 87 and the negative terminal 89 each include: a terminal body portion 92; and a shaft portion 93 protruding downward from a center portion of a lower surface of the terminal body portion 92. In such a configuration, the terminal body portion 92 and the shaft portion 93 of the positive terminal 87 are integrally formed with each other using aluminum (a single material). In the negative terminal 89, the terminal body portion 92 is made of aluminum, and the shaft portion 93 is made of copper. The negative terminal 89 is formed by assembling the terminal body portion 92 and the shaft portion 93 to each other. The terminal body portion 92 of the positive terminal 87 and the terminal body portion 92 of the negative terminal 89 are disposed at both end portions of the lid 85 via gaskets 94 made of an insulating material. The terminal body portion 92 of the positive terminal 87 and the terminal body portion 92 of the negative terminal 89 are exposed outward from the gaskets 94.

The lid 85 has a pressure release valve 95. As illustrated in FIG. 3, the pressure release valve 95 is positioned between the positive terminal 87 and the negative terminal 89. The pressure release valve 95 is released when an internal pressure in the case 82 exceeds a limit value so as to lower the internal pressure in the case 82.

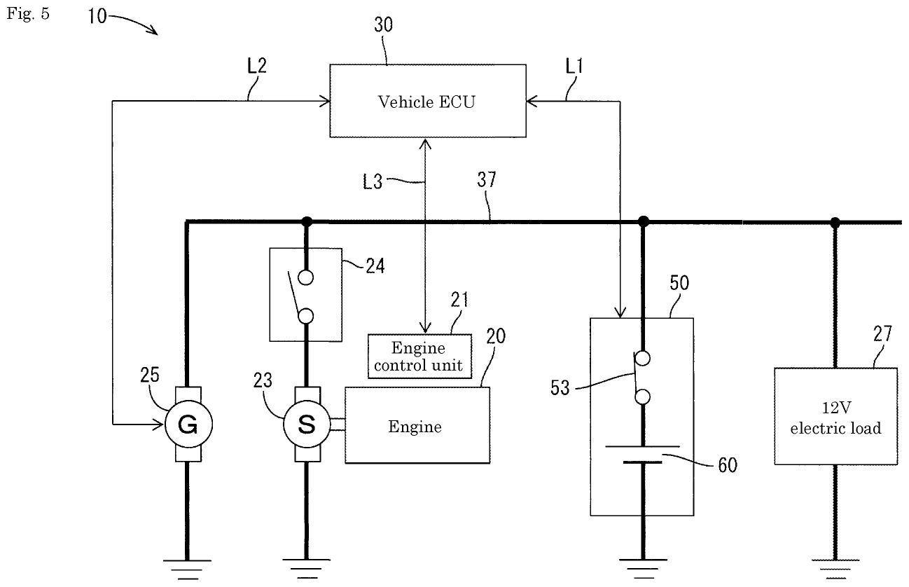

FIG. 5 is a block diagram illustrating an electrical configuration of the automobile 10, and FIG. 6 is a block diagram illustrating an electrical configuration of the battery 50.

As illustrated in FIG. 5, the automobile 10 includes an engine 20 that is a drive device, an engine control unit 21, an engine starting device 23, an alternator 25 that is a vehicle generator, an electric load 27, a vehicle electronic control unit (ECU) 30, and a battery 50.

The battery 50 is connected to an electricity supply line 37. The engine starting device 23, the alternator 25, and the electric load 27 are connected to the battery 50 via the electricity supply line 37.

The engine starting device 23 includes a starter motor. When an ignition switch 24 is turned on, a cranking current flows from the battery 50, and the engine starting device 23 is driven. A crankshaft is rotated by driving the engine starting device 23 so that the engine 20 can be started.

The electric load 27 is an electric load mounted on the automobile 10 other than the engine starting device 23. The electric load 27 has a rated voltage of 12V, and as examples of the electric load 27, an air conditioner, an audio system, and a car navigation system and the like are named.

The alternator 25 is a vehicle generator that generates electricity by the power of the engine 20. In a case where an electricity generation amount of the alternator 25 exceeds an electricity consumption amount consumed by the vehicle load of the automobile 10, the battery 50 is charged with electricity generated by the alternator 25. In a case where a power generation amount of the alternator 25 is smaller than a power consumption amount consumed by the vehicle load of the automobile 10, the battery 50 is discharged so as to compensate for a shortage of the power generation amount.

The vehicle ECU 30 is communicably connected to the battery 50 via a communication line L1, and is communicably connected to the alternator 25 via a communication line L2. The vehicle ECU 30 receives the information relating to a state of charge (SOC) from the battery 50, and controls the SOC of the battery 50 by controlling a power generation amount of the alternator 25.

The vehicle ECU 30 is communicably connected to the engine control unit 21 via a communication line L3. The engine control unit 21 is mounted on the automobile 10, and monitors an operation state of the engine 20. The engine control unit 21 monitors a traveling state of the automobile 10 based on measured values of meters such as a speed measuring instrument. The vehicle ECU 30 obtains information relating to whether the ignition switch 24 is turned on or off, information relating to an operation state of the engine 20, and information relating to a traveling state (traveling, traveling stopped, idling stop or the like) of the automobile 10 from the engine control unit 21.

As illustrated in FIG. 6, the battery 50 includes a current interruption device 53, an assembled battery 60, a current measurement unit 54, and a management device 100. The battery 50 is a battery having a rated voltage of 12V.

The current interruption device 53, the assembled battery 60, and the current measurement unit 54 are connected in series via power lines 55P, 55N. The power line 55P connects a positive external terminal 52 and a positive electrode of the assembled battery 60. The power line 55N connects a negative external terminal 51 and a negative electrode of the assembled battery 60.

The current interruption device 53 is provided to the positive power line 55P. The current measurement unit 54 is provided to the negative power line 55N.

As the current interruption device 53, a contact switch (a mechanical type switch) such as a relay or a semiconductor switch such as an FET can be used. The current interruption device 53 is always controlled to a closed state. When an abnormality occurs in the battery 50, the flow of a current is interrupted by opening the current interruption device 53 and hence, it is possible to protect the battery 50.

The current measurement unit 54 measures a current I [A] of the assembled battery 60, and outputs a measured value Im of the current to the control unit 120.

The management device 100 is mounted on the circuit board unit 65 (see FIG. 2). The management device 100 includes a voltage measurement unit 110 and the control unit 120. The control unit 120 is an example of a “correction device” and an “SOC estimation unit”.

The voltage measurement unit 110 is connected to both ends of each secondary battery cell 62 by signal lines, and measures a cell voltage V of each secondary battery cell 62. The voltage measurement unit 110 outputs the cell voltages V of the respective secondary battery cells 62 and an inter-terminal voltage VB of the assembled battery 60 obtained by summing all these voltages V to the control unit 120.

The control unit 120 includes a CPU 121 having an arithmetic operation function and a memory 123 that is a storage unit.

The control unit 120 monitors the state of the battery 50 by monitoring information relating to the current I (measured value Im of the current), information relating to the voltages V of the respective secondary battery cells 62, and information relating to the voltage VB of the assembled battery 60 that are measured by the respective measurement units 54 and 110.

The memory 123 is a nonvolatile storage medium such as a flash memory or an EEPROM. The memory 123 stores a program for monitoring the state of the assembled battery 60, programs for performing the determination flow at the time of correcting the measured value Im and at the time of estimating the SOC, and data necessary for executing the respective programs.

### 2. Method of Estimating Characteristic and SOC of Secondary Battery Cell (Assembled Battery)

The secondary battery cell 62 in the present embodiment is an LFP/Gr-based (iron phosphate-based) lithium ion secondary battery cell where lithium iron phosphate (LiFePO₄) is used as a positive active material, and graphite is used as a negative active material. In FIG. 2, one assembled battery 60 is formed by connecting 12 secondary battery cells 62 in 3 parallel and 4 series. However, one assembled battery 60 is formed by connecting four secondary battery cells 62 in series.

A current I having the same magnitude flows through the respective secondary battery cells 62 that constitute the assembled battery 60. A voltage VB of the assembled battery 60 is a value obtained by summing the voltages V of four respective secondary battery cells 62 that are connected in series. In the estimation of the SOC described below, the SOC of the assembled battery 60 is estimated.

The SOC estimation may be applied to assembled batteries having configuration other than the configuration of the assembled battery 60 that includes four secondary battery cells 62 connected in series. Although not illustrated, in a case where the battery 50 is formed of a single secondary battery cell 62, the control unit 120 may estimate the SOC of such a secondary battery cell 62.

The SOC is a ratio [%] of a residual capacity Cr [Ah] to a full-charge capacity Co [Ah] of the assembled battery 60. The SOC is expressed by the following formula (1). The full-charge capacity Co is an electricity amount that is dischargeable from the fully charged assembled battery 60.

$$SOC = ( Cr / Co ) \times 100 \qquad ( 1 )$$

As a method of estimating the SOC of the assembled battery 60 (or the secondary battery cell 62), there have been known: an estimation method that is performed based on a current of the assembled battery 60 (the secondary battery cell 62), and an estimation method that is performed based on a voltage of the assembled battery 60 (the secondary battery cell 62).

As a method of estimating the SOC based on a current, there has been known a current integration method. In the present embodiment, the first SOC is estimated using the current integration method.

In the current integration method, the SOC[%] is estimated based on a time integration value of the current I as expressed in formula (2). The symbol of the current I takes plus at the time of charging and takes minus at the time of discharging.

$$SOC = SOCo + 100 \times ( \int Idt / Co ) \qquad ( 2 )$$

$$SOCo is an initial value of SOC , I is a current , and t is an integration time .$$

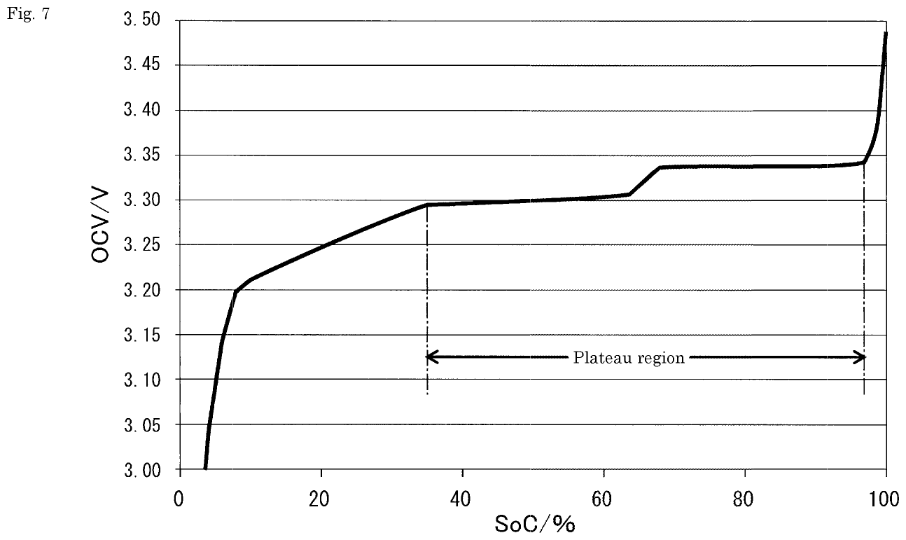

A LFP/Gr-based lithium ion secondary battery cell where a positive electrode is formed using lithium iron phosphate and a negative electrode is formed of graphite has a plateau region where a change in open circuit voltage (OCV) is small in the SOC-OCV correlation characteristic, as illustrated in FIG. 7. In the plateau region, it is difficult to estimate the SOC using the correlation between the SOC and the OCV. Accordingly, the estimation of the SOC obtained by a current integration method is generally used.

In an LFP/Gr-based lithium ion secondary battery cell or in an assembled battery using the LFP/Gr-based lithium ion secondary battery cells, a plateau region occupies most of a usable range of the battery. Accordingly, it is important to maintain the accuracy of the SOC estimation by a current integration method.

As a method of estimating the SOC based on the inter-terminal voltage VB of the assembled battery 60, there is a full charging detection method. In the present embodiment, a second SOC is estimated by the full charging detection method. The full charging detection method is a method where, in a case where the control unit 120 detects that the assembled battery 60 is charged to a voltage corresponding to the full charging, the SOC at this point of time is estimated as 100% or a predetermined set value close to 100%.

In the case of constant voltage charge, the determination as to whether the assembled battery 60 is charged to the full charging is performed by comparing the charging time after the voltage VB of the assembled battery 60 reaches a predetermined target voltage or a drooping current value with a threshold (a full charging completion condition).

The programs for performing the current integration method and the full charging detection method described above are stored in the memory 123 of the control unit 120. In a case where estimation processing of the SOC is performed in the flowchart described later, these programs are appropriately read from the memory 123 into the CPU 121.

### 3. Error Included in Measured Value of Current and Correction of Error

As illustrated in the following formula (3), a measurement error ε is included in a measured value Im of a current outputted from the current measurement unit 54. The measurement error ε is an example of a “correction value” used for correction of the measured value Im of the current as will be described later.

$$Im = Ic + ε \qquad ( 3 )$$

Im is a measured value of a current before correction, Ic is a current after correction, and ε is a measurement error.

In the estimation of the SOC using the current integration method, an error of the SOC estimation value (an SOC estimation error Se described later) is increased along with the accumulation of the measurement errors ε brought about by the supply of electricity. As a measurement error ε of a measured value Im of a current, a gain error and an offset error are mainly known. An error of an SOC estimation value attributed to a gain error is canceled by charging and discharging and hence, it is considered that an offset error is dominant as the measured error ε.

In the present embodiment, the control unit 120 estimates the SOC of the assembled battery 60 by two methods, that is, a current integration method and a full charging detection method. Using a first SOC that is obtained by a current integration method and a second SOC that is obtained by a full charging detection method, an SOC difference Sx that is a difference between the two SOCs is obtained.

The second SOC obtained by the full charging detection method has no accumulation of the measurement errors ε and hence, the second SOC has a smaller error than the first SOC that is obtained by the current integration method. The SOC difference Sx is considered as a cumulative amount of the measurement error ε included in the first SOC. Accordingly, the measurement error F included in the measured value Im of the current can be calculated based on the SOC difference Sx. In a case where an integration time t is constant, the larger the SOC difference Sx, the larger the measurement error ε becomes, and the lower the estimation accuracy of the first SOC becomes. The smaller the SOC difference Sx, the smaller the measurement error ε becomes, and the higher the estimation accuracy of the first SOC becomes.

(3) By using a measurement error ε as a correction value in the following formula (4) that is obtained by modifying the formula (3), the measured value Im of the current is corrected. By performing a current integration method using the current Ic obtained by the correction, it is possible to suppress the influence of the measurement error ε exerted on the first SOC and hence, the first SOC can be calculated with high accuracy.

$$Ic = Im - ε \qquad ( 4 )$$

### 4. Description of SOC Estimation Processing

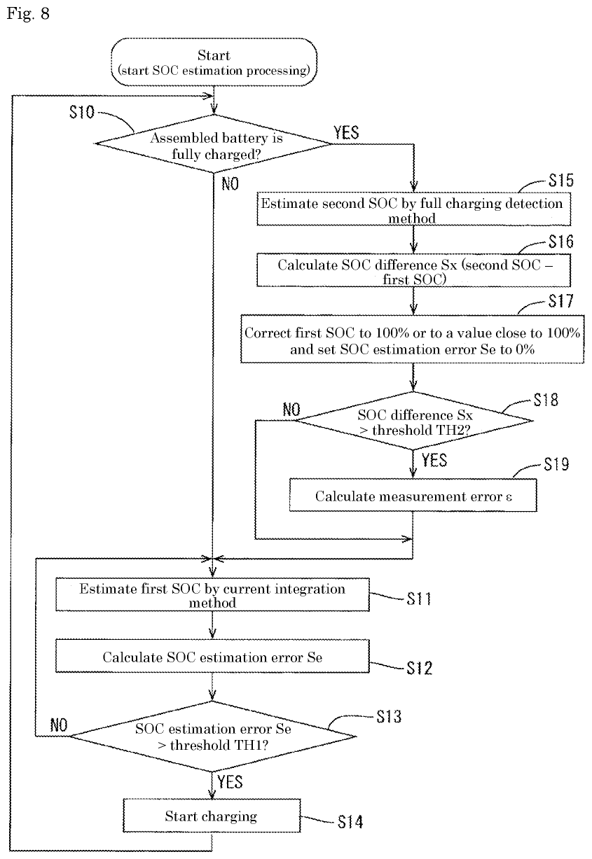

FIG. 8 is a flowchart of the SOC estimation processing. The SOC estimation processing is constituted of steps S10 to S19, and is performed at a predetermined arithmetic operation cycle T after the operation of the control unit 120 is started. The memory 123 stores an initial value SOCo of the SOC and an empirical values ε0 of the measurement errors ε.

When the control unit 120 starts the SOC estimation processing, the control unit 120 determines whether or not the assembled battery 60 is in a fully charged state based on a voltage VB of the assembled battery 60 (S10). When the SOC does not satisfy the above-described full-charge completion condition, the control unit 120 determines that the assembled battery 60 is not fully charged.

When the control unit 120 determines that the battery is not fully charged (S10: NO), the control unit 120 estimates the first SOC of the assembled battery 60 by performing the current integration method. Specifically, the control unit 120 integrates the measured values Im of the current measured by the current measurement unit 54 as expressed in the formula (2), and estimates the first SOC by adding the integrated measured value Im to the initial value SOCo of the SOC or subtracting the integrated measured value Im from the initial value SOCo, and stores the result in the memory 123.

Next, the control unit 120 calculates the SOC estimation error Se (S12). The SOC estimation error Se is an error of a magnitude that is estimated to be included in the first SOC. The measurement error ε0 (an empirical value) is integrated in accordance with the following formula (5) to calculate the SOC estimation error Se.

$$Se = \int ε 0 dt / Co \times 100 \qquad ( 5 )$$

Next, the control unit 120 compares the SOC estimation error Se with a magnitude of the threshold value TH1 (S13). The threshold value TH1 is an arbitrary value set corresponding to the estimation accuracy that the first SOC is required to satisfy. In a case where the SOC estimation error Se is smaller than the threshold value TH1 (S13: NO), the processing advances to S11, and the first SOC is estimated again by the current integration method. With respect to the SOC estimation error Se, the longer the integrated time t becomes, the larger the measurement error ε0 becomes due to accumulation, and soon the measurement error ε0 become equal to or larger than the threshold value TH1.

In a case where the control unit 120 determines that the determining that the estimation error Se is larger than the threshold value TH1 (S13: YES), the control unit 120 requests the vehicle ECU 30 to charge electricity to the assembled battery 60 (S14).

Even during the charging of electricity to the assembled battery 60, the control unit 120 continues the estimation of the first SOC by the current integration method until the assembled battery 60 is fully charged with electricity, and stores the result of the estimation in the memory 123 successively. In a case where the above-described full-charge completion condition is satisfied, the control unit 120 determines that the assembled battery 60 is fully charged (S10: YES), and estimates that the second SOC is 100% or a value close to 100% by the full charging detection method (S15).

Next, the control unit 120 calculates an absolute value of the SOC difference Sx based on the following formula (6) (S16).

$$Sx = \vert Second SOC - First SOC \vert \qquad ( 6 )$$

The SOC difference Sx is a difference between the second SOC and the first SOC at a point of time that the assembled battery 60 is charged with electricity to the full charging.

For example, assuming that the measured value Ima of the current Im is 1 A (1 m=1 A, the arithmetic operation cycle T is 0.1 s (T=0.1 s), and the full-charge capacity Co is 60 Ah (Co=60 Ah), the SOC difference Sx is calculated as follows.

The residual capacity at a point of time that the current integration method is started is set to 59.5 Ah. In a case where the full charging is detected when the arithmetic operation cycle T is repeated 1000 cycles (100 sec), the residual capacity at the time of the full charging detection is expressed by the relationship of 59.5+1×100/3600=59.528 Ah. When the residual capacity is calculated in terms of the SOC, 99.21% is obtained as the first SOC by the relationship of 59.528/60×100=99.21%.

Accordingly, in a case where it is estimated that the second SOC is 100% in step S15, the SOC difference Sx satisfies the relationship of 100−99.21=0.79% (S16).

Next, the control unit 120 corrects the first SOC to 100% or to a set value close to 100%, and sets the SOC estimation error Se to 0% (S17).

Next, the control unit 120 determines whether the SOC difference Sx is larger than the threshold value TH2 (S18).

In a case where the SOC difference Sx is smaller than the threshold value TH2 (NO in S18), the processing advances to step S11, and the control unit 120 estimates the first SOC by integrating the measured value Im of the current of the current measurement unit 54 as it is without correcting the current value Im of the measured current.

In a case where the SOC difference Sx is larger than the threshold value TH2 (S18: YES), the control unit 120 advances to S19, and calculates the measurement error ε included in the measured value Im of the current (S19).

The measurement error ε can be calculated from the following formula (7) based on a change amount Sx1 of the SOC difference Sx per unit time.

$$ε = Sx 1 \times Co / 100 \qquad ( 7 )$$

$$Sx 1 is ( the second SOC - the first SOC ) / t . That , Sx 1 is a change amount of the SOC difference Sx per unit time .$$

The control unit 120 stores the calculated measurement error ε in the memory 123. In a case where the control unit 120 calculates the measurement error ε in step S19, the processing advances to step S11. In step S11, the control unit 120 corrects the measured value Im of the current of the current measurement unit 54 by formula (4) based on the calculated measurement error ε. Then, the control unit 120 performs the current integration method using the corrected current Ic, and estimates the first SOC (S11).

The calculation and correction of the measurement error ε are not limited to one time. That is, the calculation and correction of the measurement error ε may be executed each time the SOC difference Sx exceeds the threshold value TH2. That is, in a case where the measurement error ε changes by Δε from the measurement error ε at a point of time that the previous correction is made due to a change in a state of the current measurement unit 54 or due to a change with time of the current measurement unit 54, even when the first SOC is obtained based on the corrected current Ic, an error corresponding to the change amount Δε of the measurement error ε is accumulated.

Since the accumulated change amount Δε appears as the SOC difference Sx, the change amount Δε of the measurement error ε can be obtained based on the SOC difference Sx. By correcting the measured value Im of the current at that point of time with Δε, the influence of the measurement error can be suppressed and hence, the first SOC can be estimated with high accuracy.

### 5. Description of Advantageous Effects

In the configuration described above, the control unit 120 estimates the first SOC based on the integrated value of the measured value Im of the current that flows through the assembled battery 60 (current integration method), and the control unit 120 estimates the second SOC based on the inter-terminal voltage VB of the assembled battery 60.

The measurement error ε is included in the measured value Im of the current, and the measurement error P is accumulated in the first SOC. On the other hand, the measurement error ε is not accumulated in the second SOC. Accordingly, the control unit 120 can calculate the measurement error ε included in the measured value Im of the current based on the SOC difference Sx that is the difference between the first SOC and the second SOC.

By correcting the measured value Im of the current using the calculated measurement error F as the correction value, the measured value Im of the current can be made to approach the true value and take a value close to the true value. Accordingly, the current measurement accuracy can be enhanced. By improving the accuracy of the current measurement, the accuracy of estimation of the first SOC can be improved.

The current measurement error ε includes a gain error and an offset error. The error of the SOC estimation value due to a gain error is canceled by charging and discharging the assembled battery 60. By calculating the measurement error ε included in the measured value Im of the current using the SOC difference Sx, the measured value Im of the current can be corrected without directly measuring a gain error and an offset error.

In this configuration, the control unit 120 estimates the second SOC by the full charging detection method. By setting the second SOC estimated by the full charging detection method where there is no accumulation of measurement errors ε as a target to be compared with the first SOC, the measurement error included in the SOC difference Sx can be obtained with high accuracy. As a result, the measured value Im of the current can be appropriately corrected, and the estimation accuracy of the first SOC can be enhanced.

The value of the measurement error ε may change due to a change in the surrounding environment of the current measurement unit 54 or a change of the current measurement unit 54 with time. Even in a case where the measurement error ε is calculated and the measured value Im of the current is corrected, if the measurement error ε changes thereafter, the SOC difference Sx is increased and the estimation accuracy of the first SOC is lowered.

In this configuration, even in a case where the SOCx is increased so that the SOCx exceeds the SOC difference even after the measured value Im of the current is corrected, the control unit 120 corrects the measured value Im of the current again. As a result, even if the measurement error ε fluctuates after the correction, the control unit 120 can suppress the lowering of estimation accuracy of the first SOC.

In this configuration, the control unit 120 calculates the measurement error ε based on the change amount Sx1 of the SOC difference Sx per unit time, and corrects the measured value Im of the current using the calculated measurement error ε as a correction value. By calculating the measurement error ε so as to cancel the change amount Sx1 per unit time, the estimation accuracy of the first SOC calculated by integrating the corrected current Ic can be enhanced.

### Embodiment 2

In the embodiment 1, in step S18, the control unit 120 corrects the measured value Im of the current when the “SOC difference Sx” exceeds the threshold value TH2.

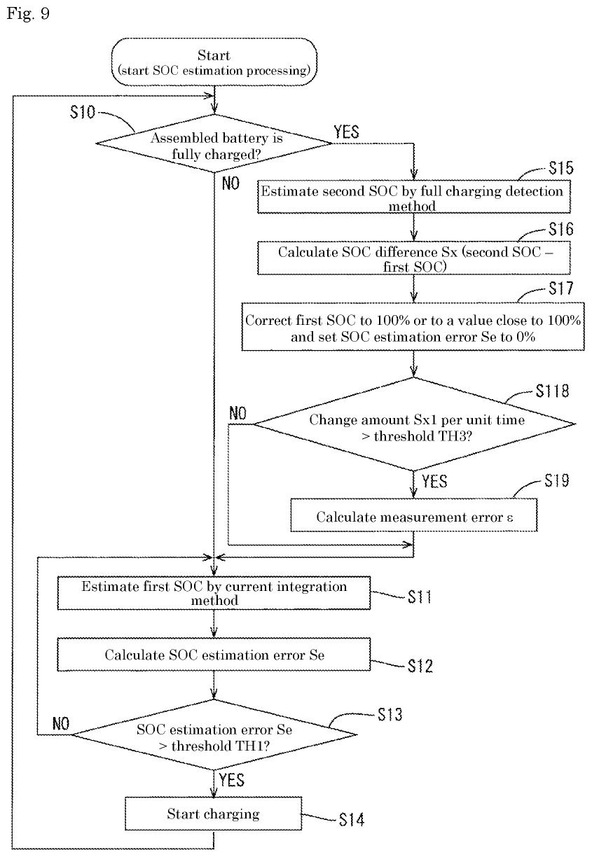

FIG. 9 is a diagram illustrating a flowchart of SOC estimation according to the embodiment 2. The flowchart illustrated in FIG. 9 differs only with respect to a point that step S18 of the embodiment 1 (FIG. 8) is changed to step S118. In step S118, the control unit 120 calculates a change amount Sx1 per unit time from the SOC difference Sx, and compares the calculated change amount Sx1 with a threshold value TH3. In a case where the change amount Sx1 exceeds the threshold value TH3 (S118: YES), the control unit 120 calculates the measurement error ε and corrects the measured value Im of the current (S19). With respect to threshold value TH3, an arbitrary value is set as the maximum allowable value of Sx1.

In a case where the change amount Sx1 per unit time of the SOC difference Sx is large, the measurement error ε included in the measured value Im of the current is large. In a case where the measurement error ε is large, the measurement error ε accumulates with the lapse of time, the estimation accuracy of the first SOC is lowered, and the SOC difference Sx is increased.

In the configuration described in the second embodiment, by detecting the increase in the change amount Sx1 per unit time, the measured value Im of the current can be corrected early. Accordingly, the lowering of the estimation accuracy of the first SOC can be suppressed.

### Other Embodiments

The present invention is not limited to the embodiments described with reference to the above description and drawings, and for example, the following embodiments are also included in the technical scope of the present invention, and various modifications other than the following can be made without departing from the gist of the present invention.

(1) In the above-mentioned embodiment, the second SOC is estimated by a full charging detection method. In addition to such a method, the second SOC estimation method may be a method of estimating a second SOC based on an OCV of the assembled battery 60 using a SOC-OCV correlation characteristic illustrated in FIG. 7.

(2) In the above embodiment, the measured value Im of the current is corrected by the formula (4). The correction formula for correcting the measured value Im of the current is not limited to the formula (4). Other formulas can be used provided that these formulas use the measurement error ε. For example, as expressed in formula (8), a formula may be used where a value obtained by multiplying the measurement error ε by a constant K that takes a positive value less than 1 may be used as a correction value.

$$Ic = Im - ε \times K \qquad ( 8 )$$

With such a configuration, even when an abnormal value irrelevant to the measurement error ε is temporarily measured in the measured value such as the measured value Im of the current, the voltage VB or the like, due to a disturbance or the like, the influence of these abnormal values on the corrected current Ic can be reduced.

(3) The secondary battery cell 62 is not limited to the lithium ion secondary battery cell, and may be other nonaqueous electrolyte secondary battery cells. The secondary battery cells 62 are not limited to be connected in series and in parallel, and may be connected in series or may be formed of a single cell. A capacitor can be also used in place of the secondary battery cell 62. The capacitor is an example of the energy storage cell.

(4) In the above embodiment, the battery 50 is provided for an automobile, but may be provided for a motorcycle. The battery 50 may be used in other moving body such as a ship, an AGV, an aircraft and the like.

(5) In the above-mentioned embodiment, the control unit 120 is disposed in the battery 50. The control unit 120 may be disposed outside the battery 50. That is, the control unit 120 that is disposed outside the battery 50 may correct the measured value Im of the current. In this case, the control unit 120 may acquire information relating to the measured value Im of the current and the voltage VB by communication from the current measurement unit 54 and the voltage measurement unit 110 disposed inside the battery 50 via communication, calculate the measurement error ε, and correct the measured value Im of the current.

(6) In the above embodiment, two configurations are exemplified. One is the configuration (the embodiment 1) where the measured value Im of the current is corrected when the SOC difference Sx exceeds the threshold value TH2. The other is the configuration (the embodiment 2) where the measured value Im of the current is corrected when the change amount Sx1 of the SOC difference Sx per unit time exceeds the threshold value TH3. The control unit 120 may correct the measured value Im of the current either in the case where the SOC difference Sx exceeds the threshold value TH2 or in the case where the change amount Sx1 per unit time exceeds the threshold value TH3.

By adopting such configuration, in a case where a change amount Sx1 per unit time is small, the measurement error ε accumulates with the lapse of time so that the SOC difference Sx is increased, and when the SOC difference Sx exceeds the threshold value TH2, the correction is performed. In a case where the change amount Sx1 per unit time is large, even if the accumulated time is short so that the SOC difference Sx is small, when the change amount Sx1 exceeds the threshold value TH3, the correction is performed. Accordingly, the correction can be performed at an appropriate time regardless of the magnitude of Sx1.

(7) In the above embodiment, the SOCs (the first SOC, the second SOC) of the assembled battery 60 are estimated, and the measurement error ε is calculated based on the SOC difference between the first SOC and the second SOC. It may be possible to adopt processing where the residual capacity (the first residual capacity and the second residual capacity) of the assembled battery 60 may be estimated using the same means as in the estimation of the SOC, and the measurement error ε may be calculated based on the residual capacity difference between the first residual capacity and the second residual capacity.

The first residual capacity [Ah] and the first SOC [%] are examples of the “first residual electricity amount” of the secondary battery cell 62 or the assembled battery 60. The second residual capacity [Ah] and the second SOC [%] are examples of the “second residual electricity amount” of the secondary battery cell 62 or the assembled battery 60. The residual capacity difference [Ah] and the SOC difference [%] are examples of the “residual electricity amount difference” of the secondary battery cell 62 or the assembled battery 60.

1. A correction device that corrects a measured value of a current of an energy storage cell or an assembled battery, wherein
the correction device is configured to calculate a correction value of the measured value of the current based on an SOC difference between a first SOC of the energy storage cell or the assembled battery estimated based on an integrated value of the measured values of the current and a second SOC of the energy storage cell or the assembled battery estimated based on a voltage of the energy storage cell or the assembled battery, and is configured to correct the measured value of the current based on the calculated correction value.

2. The correction device according to claim 1, wherein
the processing of estimating the second SOC is processing of estimating an SOC by charging the energy storage cell or the assembled battery to full charging.

3. An energy storage apparatus comprising:
the correction device according to claim 1;
the energy storage cell or the assembled battery;
a current measurement unit that measures a current of the energy storage cell or the assembled battery; and
an SOC estimation unit that estimates a first SOC of the energy storage cell or the assembled battery based on an integrated value of measured values of the currents after correction of the energy storage cell or the assembled battery.

4. The energy storage apparatus according to claim 3, wherein
the correction device corrects the measured value of the current in a case where the SOC difference exceeds a threshold.

5. The energy storage apparatus according to claim 3, wherein
the correction device corrects the measured value of the current when a change amount of the SOC difference per unit time exceeds a threshold.

6. The energy storage apparatus according to claim 3, wherein
the correction device corrects the measured value of the current using the correction value calculated based on a change amount of the SOC difference per unit time.

7. An energy storage apparatus for a vehicle according to claim 3.

8. A correction device that corrects a measured value of a current of an energy storage cell or an assembled battery, wherein
the correction device is configured to calculate a correction value of the measured value of the current based on a residual electricity amount difference that is a difference between a first residual electricity amount of the energy storage cell or the assembled battery estimated based on an integrated value of the measured values of the current and a second residual electricity amount of the energy storage cell or the assembled battery estimated based on a voltage of the energy storage cell or the assembled battery, and is configured to correct the measured value of the current based on the calculated correction value.

9. A correction method for correcting a measured value of a current of an energy storage cell or an assembled battery, the correction method comprising
calculating a correction value of the measured value of the current based on an SOC difference that is a difference between a first SOC of the energy storage cell or the assembled battery estimated based on an integrated value of the measured values of the current and a second SOC of the energy storage cell or the assembled battery estimated based on a voltage of the energy storage cell or the assembled battery, and correcting the measured value of the current based on the calculated correction value.
